(19) United States
(12) Patent Application Publication
(10) Pub. No.: US 2025/0040185 A1
(43) Pub. Date: Jan. 30, 2025

(54) SEMICONDUCTOR DEVICES

(71) Applicant: SAMSUNG ELECTRONICS CO., LTD., Suwon-si (KR)

(72) Inventors: Hyojin KIM, Suwon-si (KR); Youngdae CHO, Suwon-si (KR); Sungkeun LIM, Suwon-si (KR)

(21) Appl. No.: 18/596,247

(22) Filed: Mar. 5, 2024

(30) Foreign Application Priority Data
Jul. 26, 2023 (KR) 10-2023-0097589

(51) Int. Cl. H01L 29/417; H01L 23/528; H01L 29/06; H01L 29/423; H01L 29/66; H01L 29/775; H01L 29/786

(52) U.S. Cl. CPC H01L 29/41733; H01L 23/5283; H01L 29/0673; H01L 29/42392; H01L 29/66545; H01L 29/775; H01L 29/78696

(57) ABSTRACT

A semiconductor device may include a substrate layer; a source/drain epitaxial layer between first channel layers and second channel layers; a backside contact structure electrically connected to the source/drain epitaxial layer, wherein the backside contact structure is between the source/drain epitaxial layer and a lower surface of the substrate layer, first width of the source/drain epitaxial layer at an upper surface of the substrate layer is greater than a second width at an interface between the source/drain epitaxial layer and the backside contact structure, a first portion of the backside contact structure is closer than a closest end of the source/drain epitaxial layer to the lower surface of the substrate layer, the first portion of the backside contact structure has a third width, and the third width is greater than the second width.

### CROSS-REFERENCE TO RELATED APPLICATION(S)

This application claims benefit of priority to Korean Patent Application No. 10-2023-0097589 filed on Jul. 26, 2023 in the Korean Intellectual Property Office, the disclosure of which is incorporated herein by reference in its entirety.

### BACKGROUND

The inventive concepts of the present disclosures relate to semiconductor devices.

In line with growing demand for high performance, high speed, and/or multifunctionality of semiconductor devices, the degree of integration of semiconductor devices has increased. According to the trend for high integration of semiconductor devices, semiconductor devices having a backside power delivery network (BSPDN) structure in which power rails are disposed on a rear surface of a wafer have been developed.

### SUMMARY

An aspect of the inventive concepts of the present disclosures is to provide semiconductor devices having improved reliability.

According to an aspect of the inventive concepts of the present disclosures, a semiconductor device may include a substrate layer; first channel layers that are spaced apart from each other on the substrate layer in a first direction, wherein the first direction is perpendicular to an upper surface of the substrate layer; second channel layers that are spaced apart from each other on the substrate layer in the first direction and spaced apart from the first channel layers; a first gate structure that extends in a second direction and extends around each of the first channel layers, wherein the second direction is parallel with the upper surface of the substrate layer; a second gate structure that extends in the second direction and extends around each of the second channel layers; a source/drain epitaxial layer between the first channel layers and the second channel layers; a backside contact structure that is electrically connected to the source/drain epitaxial layer, wherein the backside contact structure is between the source/drain epitaxial layer and a lower surface of the substrate layer in the first direction; and an interlayer insulating layer on the source/drain epitaxial layer, wherein, along a third direction that is parallel with the upper surface of the substrate layer, a first width of the source/drain epitaxial layer at the upper surface of the substrate layer is greater than a second width at an interface between the source/drain epitaxial layer and the backside contact structure, wherein a first portion of the backside contact structure is closer than a closest end of the source/drain epitaxial layer to the lower surface of the substrate layer, wherein the lower surface of the substrate layer is opposite to the upper surface of the substrate layer along the first direction, wherein the first portion of the backside contact structure has a third width, and wherein the third width is greater than the second width.

According to another aspect of the inventive concepts of the present disclosures, a semiconductor device may include a substrate layer; first channel layers that are spaced apart from each other on the substrate layer in a first direction, wherein the first direction is perpendicular to an upper surface of the substrate layer; second channel layers that are spaced apart from each other on the substrate layer in the first direction and spaced apart from the first channel layers; a first gate structure that extends in a second direction and extends around each of the first channel layers, wherein the second direction is parallel with the upper surface of the substrate layer; a second gate structure that extends in the second direction and extends around each of the second channel layers; a source/drain epitaxial layer between the first channel layers and the second channel layers; a backside contact structure that is electrically connected to the source/drain epitaxial layer, wherein the backside contact structure is between the source/drain epitaxial layer and a lower surface of the substrate layer in the first direction; and an interlayer insulating layer on the source/drain epitaxial layer, wherein at least a portion of the backside contact structure has a side surface that is inclined such that a width of the backside contact structure in a third direction increase toward the source/drain epitaxial layer, wherein the lower surface of the substrate layer is opposite to the upper surface of the substrate layer in the first direction, and wherein the third direction is parallel with the upper surface of the substrate layer and perpendicular to the second direction.

According to another aspect of the inventive concepts of the present disclosures, a semiconductor device may include a substrate layer; first channel layers that are spaced apart from each other on the substrate layer in a first direction, wherein the first direction is perpendicular to an upper surface of the substrate layer; second channel layers that are spaced apart from each other on the substrate layer in the first direction and spaced apart from the first channel layers; a first gate structure that extends in a second direction and extends around each of the first channel layers, wherein the second direction is parallel with the upper surface of the substrate layer; a second gate structure that extends in the second direction and extends around each of the second channel layers; a source/drain epitaxial layer between the first channel layers and the second channel layers; a backside contact structure that is electrically connected to the source/drain epitaxial layer, wherein the backside contact structure is between the source/drain epitaxial layer and a lower surface of the substrate layer; and an interlayer insulating layer on the source/drain epitaxial layer, wherein the lower surface of the substrate layer is opposite to the upper surface of the substrate layer in the first direction, an interface between the source/drain epitaxial layer and the backside contact structure is closer than the first gate structure and second gate structure that are adjacent to the source/drain epitaxial layer to the upper surface of the substrate layer, a maximum width of the backside contact structure in a third direction is greater than a minimum width of the source/drain epitaxial layer in the third direction, the source/drain epitaxial layer has the minimum width in the third direction at a same distance as at least one of the first channel layers from the upper surface of the substrate layer in the first direction, and the third direction is parallel with the upper surface of the substrate layer and perpendicular to the second direction.

### BRIEF DESCRIPTION OF DRAWINGS

The above and other aspects, features, and advantages of the inventive concepts of the present disclosures will be more clearly understood from the following detailed description, taken in conjunction with the accompanying drawings, in which:

FIG. 1 is a schematic plan view illustrating a semiconductor device according to example embodiments;

FIG. 2A is schematic cross-sectional views illustrating a semiconductor device according to example embodiments;

FIG. 2B are schematic cross-sectional views illustrating a semiconductor device according to example embodiments;

FIG. 3 is schematic cross-sectional views illustrating a semiconductor device according to example embodiments;

FIG. 4 is schematic cross-sectional views illustrating a semiconductor device according to example embodiments;

FIG. 5 is schematic cross-sectional views illustrating a semiconductor device according to example embodiments;

FIGS. 6A to 6B are flowcharts schematically illustrating a sequential process of a method of manufacturing a semiconductor device according to example embodiments;

FIG. 7 is a flowchart schematically illustrating a sequential process of a method of manufacturing a semiconductor device according to example embodiments;

FIG. 8 is a flowchart schematically illustrating a sequential process of a method of manufacturing a semiconductor device according to example embodiments;

FIGS. 9 to 20 are drawings according to a process sequence to explain a method of manufacturing a semiconductor device according to example embodiments; and

FIGS. 21 to 23 are views illustrating a process sequence to explain a method of manufacturing a semiconductor device according to example embodiments.

### DETAILED DESCRIPTION

Hereinafter, example embodiments of the present inventive concept will be described with reference to the accompanying drawings. Hereinafter, terms, such as ‘top’, ‘upper portion’, ‘upper surface’, ‘bottom’, ‘lower portion’, ‘lower surface’, and ‘side surface’ may be understood as referring to based on drawings, except for cases indicated by reference numerals. The terms “lower”, “higher”, “lower level”, “higher level”, and the like may refer to a relative distance from the upper/lower surface of the substrate (e.g., the substrate layer 194) in a vertical direction (e.g., Z-direction). For example, when an element A is described as lower than an element B, the element A may be closer than the element B to the upper/lower surface of the substrate in the vertical direction.

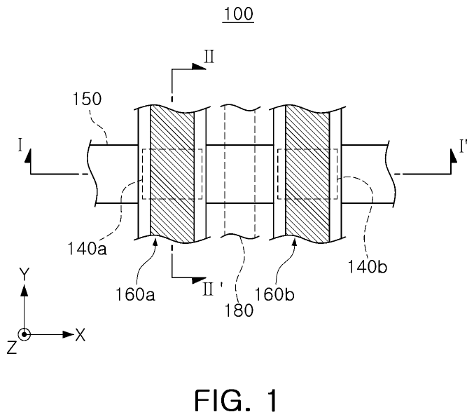

FIG. 1 is a schematic plan view illustrating a semiconductor device according to example embodiments.

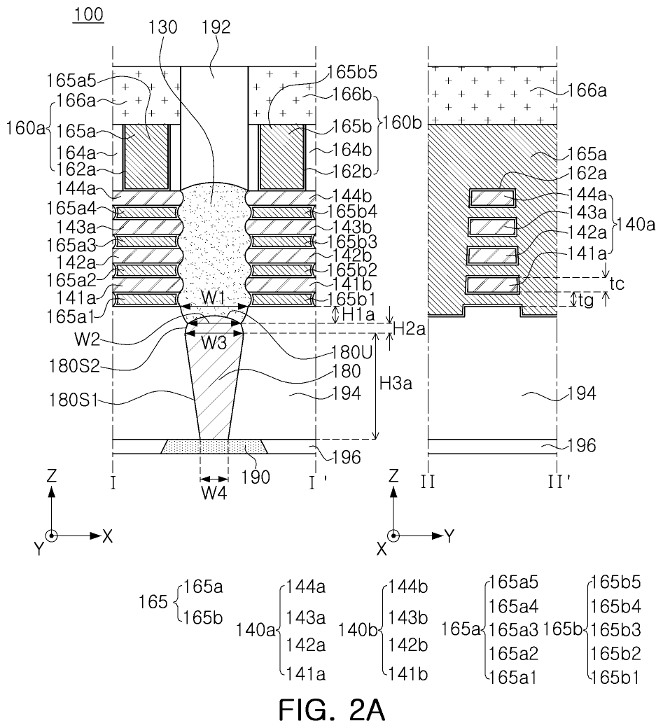

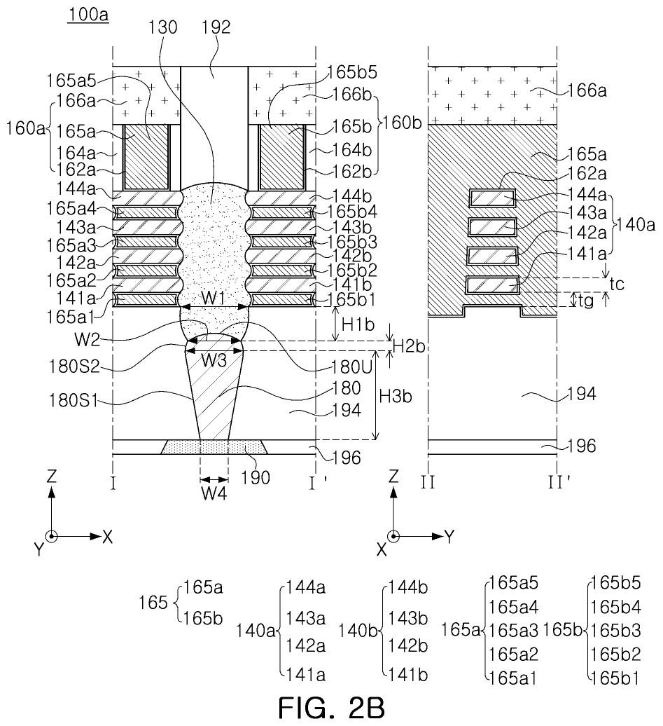

FIG. 2A is a schematic cross-sectional view illustrating a semiconductor device according to example embodiments. FIG. 2A illustrates cross-sections of the semiconductor device of FIG. 1 taken along lines I-I′ and II-II′. For convenience of description, only some components of the semiconductor device are illustrated in FIG. 1.

Referring to FIGS. 1 and 2A, a semiconductor device 100 may include a substrate layer 194, gate structures 160a and 160b (also referred to as first and second gate structures 160a and 160b) extending in one direction (e.g., X-direction or Y-direction) on the substrate layer 194. The first gate structure 160a may include a first gate electrode 165a and a first channel structure 140a that includes first channel layers 141a, 142a, 143a, and 144a. The first channel layers 141a, 142a, 143a, and 144a may be spaced apart from each other in a vertical direction (e.g., Z-direction). The second gate structure 160b may include a second gate electrode 165b and a second channel structure 140b that includes second channel layers 141b, 142b, 143b, and 144b. The second channel layers 141b, 142b, 143b, and 144b may be spaced apart from each other in the vertical direction (e.g., Z-direction). The semiconductor device 100 may further include a source/drain epitaxial layer 130 between the first and second gate structures 160a and 160b, and the source/drain epitaxial layer 130 may contact the first and second channel structures 140a and 140b. The semiconductor device 100 may further include a backside contact structure 180 connected (e.g., electrically connected) to the source/drain epitaxial layer 130 through a substrate layer 194, and a backside interconnection 190 connected (e.g., electrically connected) to the backside contact structure 180. For example, the backside contact structure 180 may extend in the substrate layer 194 to be (electrically) connected to the source/drain epitaxial layer 130. The semiconductor device 100 may further include an interlayer insulating layer 192 on the source/drain epitaxial layer 130 and a rear insulating layer 196 on a lower surface of the substrate layer 194. It will be understood that when an element or layer is referred to as being “connected to”, or “coupled to” another element or layer, it may be directly on, connected to, or coupled to the other element or layer, or one or more intervening elements or layers may be present. In contrast, when an element is referred to as being “directly coupled,” “directly connected,” or “directly responsive” to, or “directly on,” another element, there are no intervening elements present. In addition, “electrical connection” conceptually includes a physical connection and a physical disconnection. In addition, it will also be understood that when an element or layer is referred to as being “between” two elements or layers, it may be the only element or layer between the two elements or layers, or one or more intervening elements or layers may also be present.

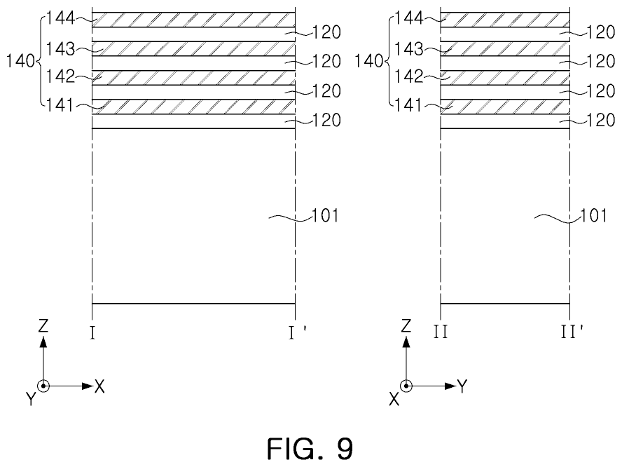

The substrate layer 194 may have an upper surface extending in the X-direction and the Y-direction. The X-direction and the Y-direction may be parallel with the upper surface of the substrate layer 194 and may intersect with each other. The X-direction may be perpendicular to the Y-direction. The Z-direction may be perpendicular to the upper surface of the substrate layer 194. The Z-direction may intersect with the X-direction and the Y-direction. The substrate layer 194 may be formed by removing and/or oxidizing a substrate 101 (refer to FIG. 9) that includes a semiconductor material. The substrate layer 194 may include, for example, an insulating material, such as oxide, nitride, or combinations thereof. According to some embodiments, the substrate layer 194 may include a plurality of insulating layers.

In some embodiments, the gate structures 160a and 160b may be disposed on the substrate layer 194 to extend in one direction, for example, in the Y-direction. Channel regions of transistors may be formed in channel structures 140a and 140b (also referred to as the first and second channel structures 140a and 140b) crossing (e.g., overlapping in the Z-direction) gate electrodes 165a and 165b (also referred to as first and second gate electrodes 165a and 165b) of the gate structures 160a and 160b. The first gate structure 160a and the second gate structure 160b may be spaced apart from each other in the X-direction. The first and second gate structures 160a and 160b may include first and second gate dielectric layers 162a and 162b (also collectively referred to as gate dielectric layers 162a and 162b), first and second gate spacer layers 164a and 164b (also collectively referred to as gate spacer layers 164a and 164b), and the first and second gate electrodes 165a and 165b, respectively. The first and second gate structures 160a and 160b may further include first and second capping layers 166a and 166b (also collectively referred to as capping layers 166a and 166b) on upper surfaces of the first and second gate electrodes 165a and 165b, respectively. As used herein, “an element A overlapping an element B in a direction X” (or similar language) means that there is at least one line that extends in the direction X and intersects both the elements A and B.

The first and second gate dielectric layers 162a and 162b may be disposed between the substrate layer 194 and the first and second gate electrodes 165a and 165b (respectively). The first and second gate dielectric layers 162a and 162b may be disposed between the first and second channel structures 140a and 140b and the first and second gate electrodes 165a and 165b (respectively). The first and second gate dielectric layers 162a and 162b may be disposed on (e.g., cover) at least some (portions) of the surfaces of the first and second gate electrodes 165a and 165b (respectively). The first and second gate dielectric layers 162a and 162b may extend between the first and second gate electrodes 165a and 165b and the first and second gate spacer layers 164a and 164b, (respectively) but are not limited thereto. The gate dielectric layers 162a and 162b may include, for example, an oxide, a nitride, and/or a high-k material. The high-K material may refer to a dielectric material having a dielectric constant higher than that of silicon oxide (SiO₂). The high-K material may include, for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃). According to example embodiments, (each of or at least one of) the first and second gate dielectric layers 162a and 162b may have a multilayer structure.

The gate electrodes 165a and 165b may include a conductive material, for example, a metal nitride, such as titanium nitride (TiN), tantalum nitride (TaN), or tungsten nitride (WN), a metal material, such as aluminum (Al), tungsten (W), or molybdenum (Mo), and/or a semiconductor material, such as doped polysilicon. According to example embodiments, (each of or at least one of) the first and second gate electrodes 165a and 165b may have a multilayer structure.

The first and second gate spacer layers 164a and 164b may be (respectively) disposed on both (e.g., opposite) side surfaces of the first and second gate electrodes 165a and 165b on the first and second channel structures 140a and 140b. The gate spacer layers 164a and 164b may insulate (e.g., electrically insulate) the source/drain epitaxial layer 130 and the gate electrodes 165a and 165b from each other. According to example embodiments, the shape of upper ends of the gate spacer layers 164a and 164b may be variously changed, and (each of or at least one of) the first and second gate spacer layers 164a and 164b may have a multilayer structure. The gate spacer layers 164 may include, for example, oxide, nitride, oxynitride, and/or a low-κ material.

The first and second channel structures 140a and 140b may be disposed on the substrate layer 194 to cross (e.g., overlap in the Z-direction) the first and second gate structures 160a and 160b (respectively). The first and second channel structures 140a and 140b may respectively include the first channel layers 141a, 142a, 143a, and 144a and the second channel layers 141b, 142b, 143b, and 144b, which are two or more channel layers spaced apart from each other in the Z-direction. The channel structures 140a and 140b may be connected (e.g., in contact with or electrically connected) to the source/drain epitaxial layer 130. The first and second channel structures 140a and 140b may have a width the same as or similar to that of the first and second gate structures 160a and 160b in the X-direction, respectively. In a cross-section in the Y-direction, among the first and second channel layers 141a, 142a, 143a, and 144a and 141b, 142b, 143b, and 144b, the lower channel layer may have a width equal to or greater than that of the upper channel layer. For example, a channel layer 141a among the first channel layers 141a, 142a, 143a, and 144a may have a width (in the X-direction and/or the Y-direction) be equal to or less than that of another channel layer 142a among the first channel layers 141a, 142a, 143a, and 144a. In some example embodiments, the first and second channel structures 140a and 140b may have a reduced width compared to the first and second gate structures 160a and 160b so that side surfaces of the first and second channel structures 140a and 140b are located below the first and second gate structures 160a and 160b, respectively. For example, the side surfaces of the first and second channel structures 140a and 140b may overlap the first and second gate structures 160a and 160b in the Z-direction, respectively, but the embodiments of the inventive concepts of the present disclosures are not limited thereto. For example, side surfaces of the first and second gate structures 160a and 160b may overlap the first and second channel structures 140a and 140b in the Z-direction, respectively.

The channel structures 140a and 140b may include a semiconductor material, for example, silicon (Si), silicon germanium (SiGe), and/or germanium (Ge). The number and shape of channel layers constituting one of the first and second channel structures 140a and 140b may be variously changed in example embodiments.

In the semiconductor device 100, the first and second gate electrodes 165a and 165b may be respectively disposed between the first and second channel layers 141a, 142a, 143a, and 144a and 141b, 142b, 143b, and 144b of the first and second channel structures 140a and 140b and on the first and second channel structures 140a and 140b. For example, the first gate electrode 165a may include first gate electrode layers 165a1, 165a2, 165a3, 165a4, and 165a5. The first channel layers 141a, 142a, 143a, and 144a may be respectively disposed on the first gate electrode layers 165a1, 165a2, 165a3, and 165a4, and the gate electrode layer 165a5 disposed on the first channel structure 140a (e.g., the first channel layer 144a). For example, the first gate electrode layers 165a1, 165a2, 165a3, 165a4, and 165a5 and the first channel layers 141a, 142a, 143a, and 144a may be alternately stacked in the Z-direction. Accordingly, the semiconductor device 100 may include a MBCFET™ (Multi Bridge Channel FET), which is a type of gate-all-around type field effect transistor.

The source/drain epitaxial layer 130 may be disposed to contact the channel structures 140a and 140b on both sides of the gate structures 160a and 160b, respectively. The source/drain epitaxial layer 130 may be on (e.g., cover) side surfaces of each of the first and second channel layers 141a, 142a, 143a, and 144a and 141b, 142b, 143b, and 144b of the first and second channel structures 140a and 140b. A width of a portion in which the source/drain epitaxial layer 130 contacts each of the first and second channel layers 141a, 142a, 143a, and 144a and 141b, 142b, 143b, and 144b in the X-direction may be less than a width of a portion in which the source/drain epitaxial layer 130 contacts each of the first and second gate electrodes 165a (e.g., the first gate electrode layers 165a1, 165a2, 165a3, and 165a4) and 165b (e.g., the second gate electrode layers 165b1, 165b2, 165b3, and 165b4) in the X-direction. According to the example embodiment, the width of the source/drain epitaxial layer 130 in the X-direction may be constant, but is not limited thereto. The source/drain epitaxial layer 130 may be connected (e.g., electrically connected) to the backside contact structure 180 through a lower surface or a lower end. For example, the lower surface or the lower end of the source/drain epitaxial layer 130 may be in contact with an upper surface or an upper end of the backside contact structure 180. The source/drain epitaxial layer 130 may be electrically connected to the backside interconnection 190 through the backside contact structure 180 to receive power. An upper surface of the source/drain epitaxial layer 130 may be located at a height (e.g., a distance from the upper or lower surface of the substrate layer 194 in the Z-direction) the same as or similar to that of a lower surface of the gate electrode 165 on the channel structure 140, and the height may be variously changed in example embodiments. The source/drain epitaxial layer 130 may include a semiconductor material, for example, silicon (Si) and/or germanium (Ge), and may further include impurities.

The backside contact structure 180 may be disposed below the source/drain epitaxial layer 130 to contact a lower surface of the source/drain epitaxial layer 130. The backside contact structure 180 may extend in (e.g., pass through or at least partially penetrate) the substrate layer 194 and be connected (e.g., electrically connected) to the source/drain epitaxial layer 130. A width of a portion in which the source/drain epitaxial layer 130 contacts the upper surface of the substrate layer 194 may have a first width W1 in the X-direction. For example, the source/drain epitaxial layer 130 may have the first width W1 in the X-direction at the height of the upper surface of the substrate layer 194. A width of a portion (of the backside contact structure 180) at which the source/drain epitaxial layer 130, the backside contact structure 180, and the substrate layer 194 simultaneously contact each other may have a second width W2 in the X-direction. For example, the greatest width of the backside contact structure 180 in the X-direction at a height where the source/drain epitaxial layer 130 and the backside contact structure 180 contact to each other may be the second width W2. The first width W1 may be greater than the second width W2. The backside contact structure 180 may include a portion having a third width W3 greater than the second width W2 in the X-direction on a level (a height) lower than the portion having the second width W2. Accordingly, the slope of the side surfaces of the source/drain epitaxial layer 130 and the backside contact structure 180 may discontinuously change at the portion (of the backside contact structure 180) having the second width W2. For example, the side surfaces of the source/drain epitaxial layer 130 and the backside contact structure 180 may not be continuously (e.g., uniformly, smoothly, or conformally) connected to each other.

The lower surface of the backside contact structure 180 may have a fourth width W4 in the X-direction, and the fourth width W4 may be less than the second width W2 of the backside contact structure 180. The portion of the backside contact structure 180 having the second width W2 may be located to be closer to the portion of the backside contact structure 180 having the third width W3 than the portion of the source/drain epitaxial layer 130 having the first width W1. That is, a first level difference H1a between the portion of the source/drain epitaxial layer 130 having the first width W1 and the portion of the backside contact structure 180 having the second width W2 may be greater than a second level difference H2a between the portion of the backside contact structure 180 having the second width W2 and the portion of the backside contact structure 180 having the third width W3. A third level difference H3a between the portion of the backside contact structure 180 having the third width W3 and the lower surface of the backside contact structure 180 (having the fourth width W4) may be greater than the first level difference H1a and the second level difference H2a. The third width W3 of the backside contact structure 180 may be less than the maximum width of the source/drain epitaxial layer 130 (in the X-direction), but is not limited thereto. For example, the third width W3 may be greater than or substantially equal to the first width W1.

An upper surface 180U of the backside contact structure 180 may have a convex shape in a direction toward the source/drain epitaxial layer 130. The uppermost end of the backside contact structure 180 may be located on a level higher than the lowermost end of the source/drain epitaxial layer 130.

A first side surface 180S1 between the portion having the third width W3 and the portion having the fourth width W4 in the backside contact structure 180 may have a negative slope so that the width of the backside contact structure 180 (for example, in the X-direction and/or in the Y-direction) narrows toward the lower surface of the backside contact structure 180. A second side surface 180S2 of the backside contact structure 180 between the portion having the second width W2 and the portion having the third width W3 in the backside contact structure 180 may have a positive slope so that the width of the backside contact structure 180 (for example, in the X-direction and/or in the Y-direction) widens toward the lower surface of the backside contact structure 180. Reliability of the backside contact structure 180 and the source/drain epitaxial layers 130 may be improved because the backside contact structure 180 and the source/drain epitaxial layers 130 have a discontinuously changing lateral (side surface) slope at the portion having the second width W2.

Although not specifically shown in the drawings, the substrate layer 194 may further include an insulating layer. The insulating layer may be disposed on (e.g., to contact) the side surfaces of the backside contact structure 180 and the side surface of the source/drain epitaxial layer 130 located at a level (a height) lower than those of the first and second gate structures 160a and 160b.

The backside interconnection 190 may be connected (e.g., electrically connected) to a lower end or lower surface of the backside contact structure 180. The backside contact structure 180 may be on the backside interconnection 190. The backside interconnection 190, together with the backside contact structure 180, may form a backside power delivery network (BSPDN) that applies power or ground voltage to the semiconductor device 100, and may be referred to as a backside power rail or a buried power rail. For example, the backside interconnection 190 may be a buried interconnection line extending from below the backside contact structure 180 in one direction, for example, in the Y-direction, but the shape of the backside interconnection 190 is not limited thereto. For example, in some example embodiments, the backside interconnection 190 may include a via region and/or a line region. A width of the backside interconnection 190 may continuously increase downwardly, but is not limited thereto.

A width of the upper surface 180U (e.g., the second width W2) of the backside contact structure 180 (in the X-direction) may be greater than the fourth width W4 of the lower end of the backside contact structure 180, and the central axis of the backside interconnection 190 may be disposed to match the central axis of the backside contact structure 180.

The backside interconnection 190 may include, for example, a conductive material, such as tungsten (W), copper (Cu), aluminum (Al), cobalt (Co), ruthenium (Ru), titanium (Ti), and/or molybdenum (Mo).

The interlayer insulating layer 192 may be disposed on (e.g., to cover) upper surfaces of the source/drain epitaxial layer 130 and the gate structures 160a and 160b. A rear insulating layer 196 may be disposed on (e.g., to cover) the lower surface of the substrate layer 194 and extend around (e.g., surround) the backside interconnection 190. The interlayer insulating layer 192 and the rear insulating layer 196 may include, for example, oxide, nitride, oxynitride, and/or a low-κ material. According to example embodiments, each of the interlayer insulating layer 192 and the rear insulating layer 196 may include a plurality of insulating layers.

The semiconductor device 100 may be packaged by inverting the structure of FIG. 2A so that the backside interconnection 190 is located on the upper side, but a packaging form of the semiconductor device 100 is not limited thereto. Since the source/drain epitaxial layer 130 is connected to the backside interconnection 190 therebelow through the backside contact structure 180, the degree of integration may be improved.

In the description of the following example embodiments, the same descriptions given above with reference to FIGS. 1 to 2A may be omitted.

FIGS. 2B to 5 are schematic cross-sectional views illustrating a semiconductor device according to example embodiments.

Referring to FIG. 2B, in a semiconductor device 100a, a first level difference H1b between the portion of the source/drain epitaxial layer 130 having the first width W1 and the portion of the backside contact structure 180 having the second width W2 may be greater than a channel thickness tc of the first channel layer 141a located at the lowermost portion of the first channel structure 140a. According to an example embodiment, the first level difference H1b may be twice or more the channel thickness tc.

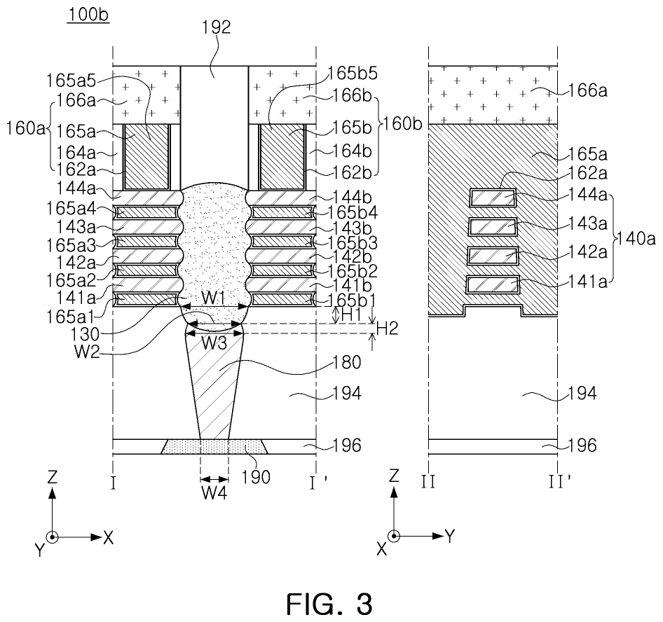

Referring to FIG. 3, in a semiconductor device 100b, a lower surface of the source/drain epitaxial layer 130 may have a convex shape in a direction toward the backside contact structure 180. The source/drain epitaxial layer 130 may have the second width W2 at a portion where the source/drain epitaxial layer 130 simultaneously contacts both the substrate layer 194 and the backside contact structure 180. The side surfaces of the source/drain epitaxial layer 130 and the backside contact structure 180 may have discontinuously changing slopes at the portion having the second width W2.

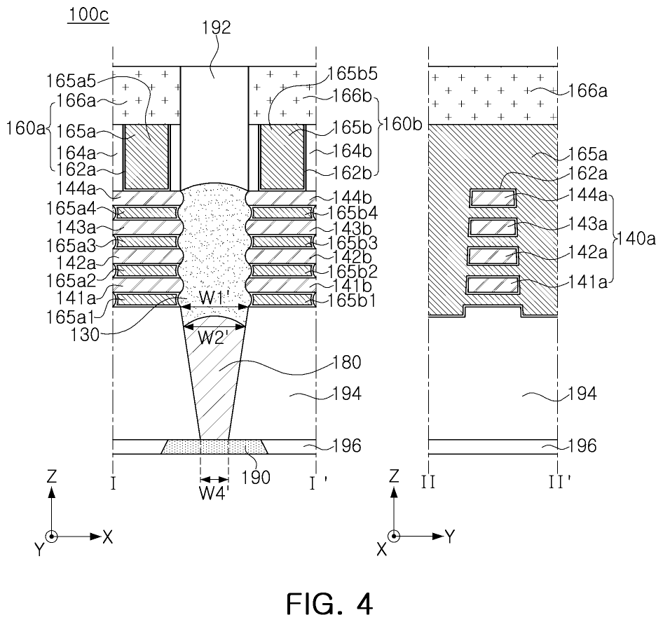

Referring to FIG. 4, in a semiconductor device 100c, at least a portion of the backside contact structure 180 may have side surfaces inclined to widen toward the source/drain epitaxial layer 130. At a level (height) lower than the upper surface of the substrate layer 194, the source/drain epitaxial layer 130 may have a side surface inclined to narrow toward the backside contact structure 180. That is, a first width W1′ of a portion of the source/drain epitaxial layer 130 at which the source/drain epitaxial layer 130 contacts the upper surface of the substrate layer 194 may be greater than a second width W2′ a portion of the backside contact structure 180 at which the backside contact structure 180 contacts the lowermost end of the source/drain epitaxial layer 130. For example, the source/drain epitaxial layer 130 may have the first width W1′ in the X-direction at the same height as the upper surface of the substrate layer 194. The backside contact structure 180 may have the second width W2′ in the X-direction at the same height as the lowermost end of the source/drain epitaxial layer 130. The first width W1′ may be greater than the second width W2′. The slope of the side surface of the source/drain epitaxial layer 130 and the slope of the side surface of the backside contact structure 180 may be the same, but are not limited thereto. For example, the side surface of the source/drain epitaxial layer 130 and the side surface of the backside contact structure 180 may be connected to each other smoothly (without a kink).

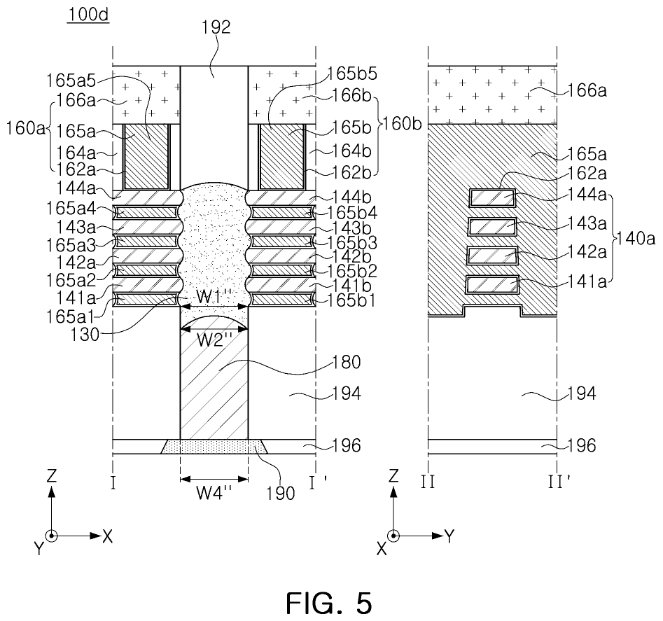

Referring to FIG. 5, in a semiconductor device 100d, the maximum width of the backside contact structure 180 may be greater than the minimum width of portions of the source/drain epitaxial layer 130 in the first direction (e.g., X-direction) and/or the second direction (e.g., the Y-direction). A first width W1″ of the portion in which the source/drain epitaxial layer 130 contacts the upper surface of the substrate layer 194 and a second width W2″ of a portion in which the backside contact structure 180 contacts the lowermost end of the source/drain epitaxial layer 130 may be substantially the same. For example, the source/drain epitaxial layer 130 may have the first width W1″ in the X-direction at the same height as the upper surface of the substrate layer 194. The backside contact structure 180 may have the second width W2″ in the X-direction at the same height as the lowermost end of the source/drain epitaxial layer 130. The first width W1″ and the second width W2″ may be substantially the same. The source/drain epitaxial layer 130 may have a constant width below the portion having the first width W1″, and the backside contact structure 180 may have a constant width below the portion having the second width W2″. A fourth width W4″ of the lower end of the backside contact structure 180 may be greater than the minimum width of portions of the source/drain epitaxial layer 130 in the first direction (e.g., X-direction) and/or the second direction (e.g., the Y-direction).

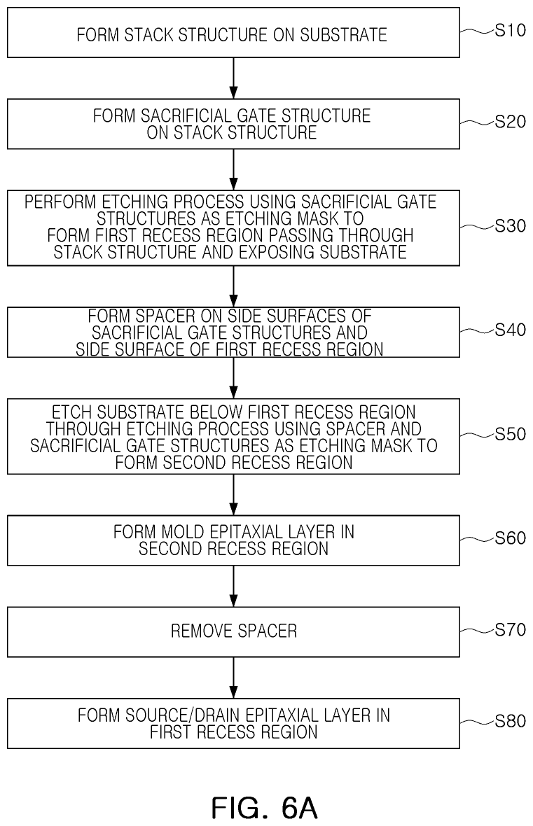

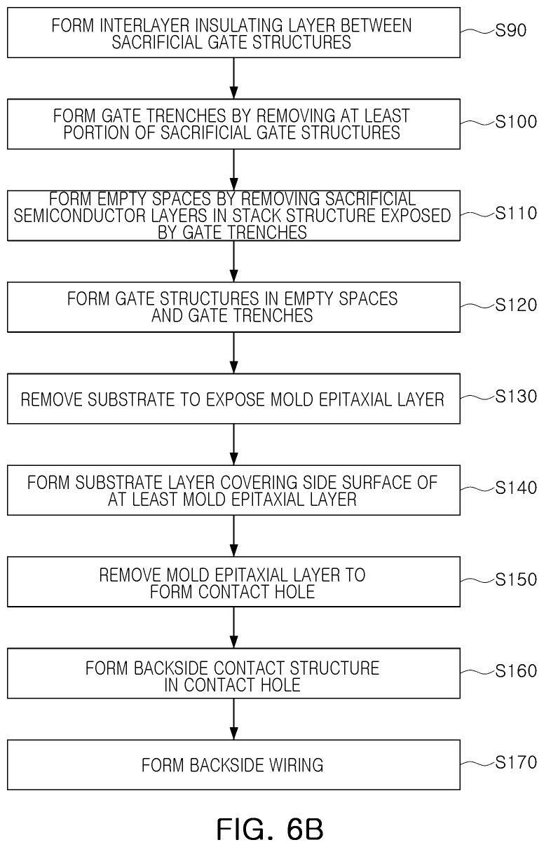

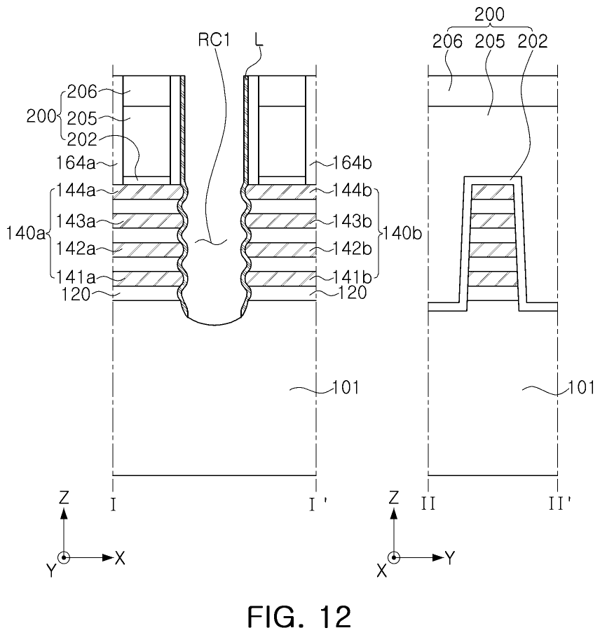

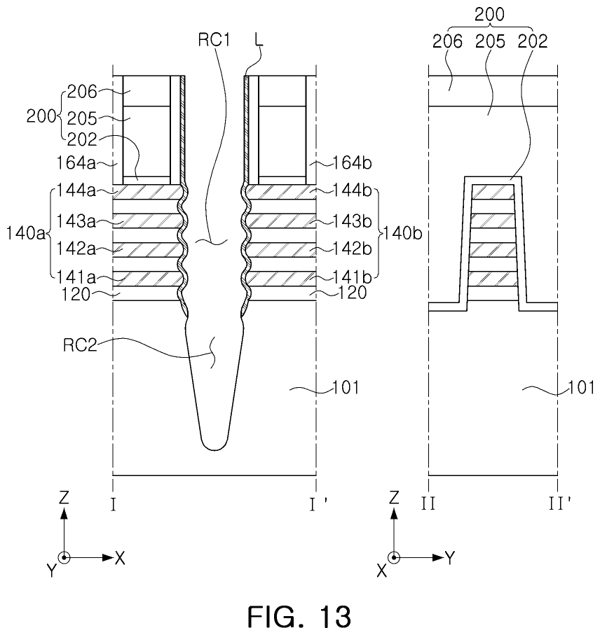

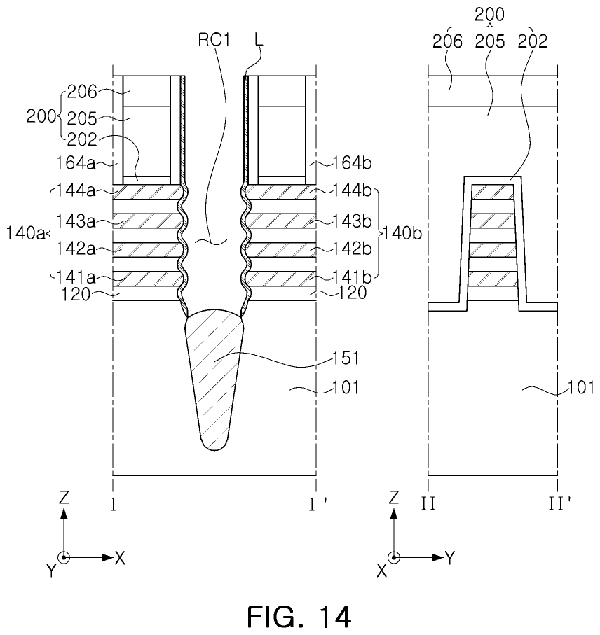

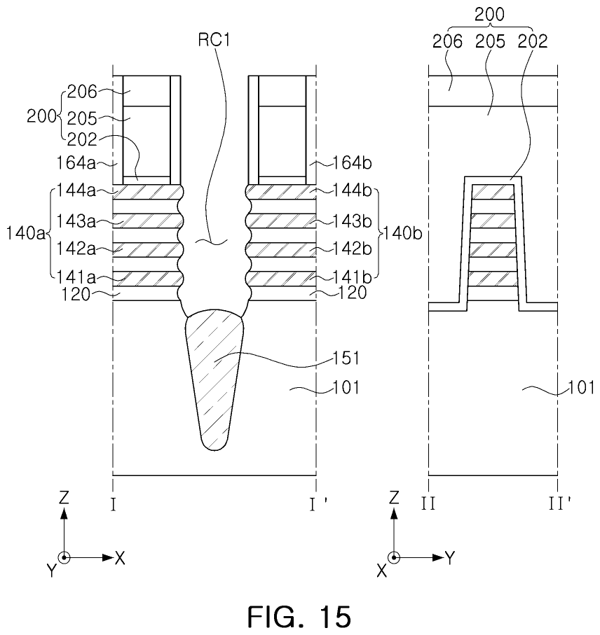

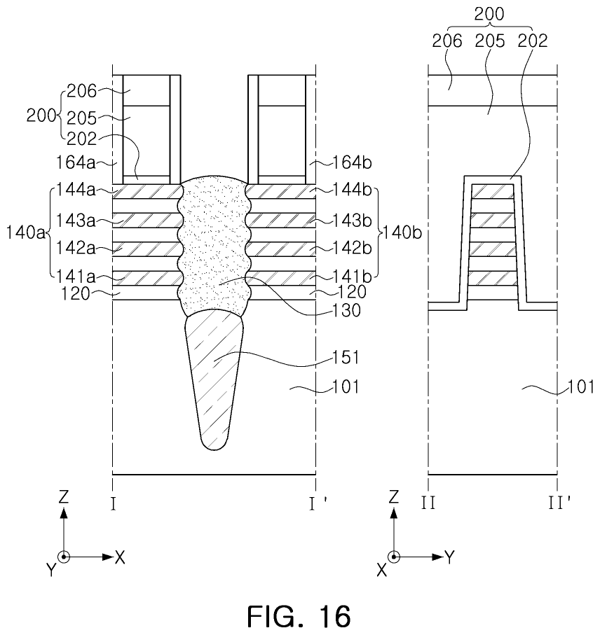

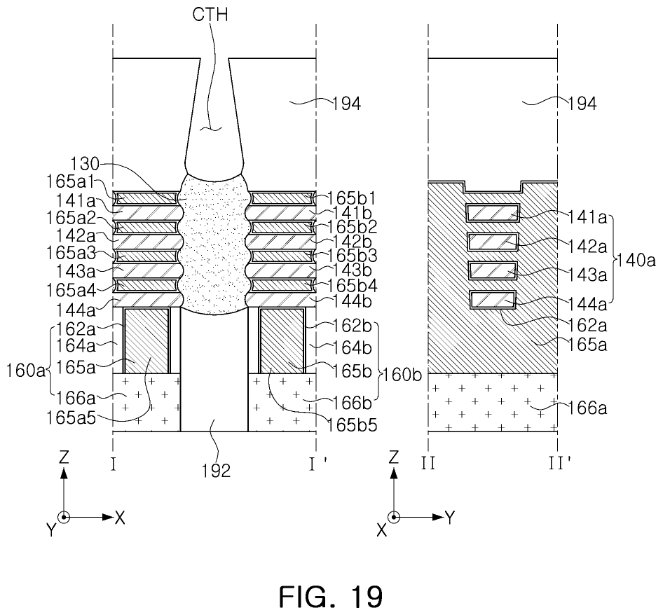

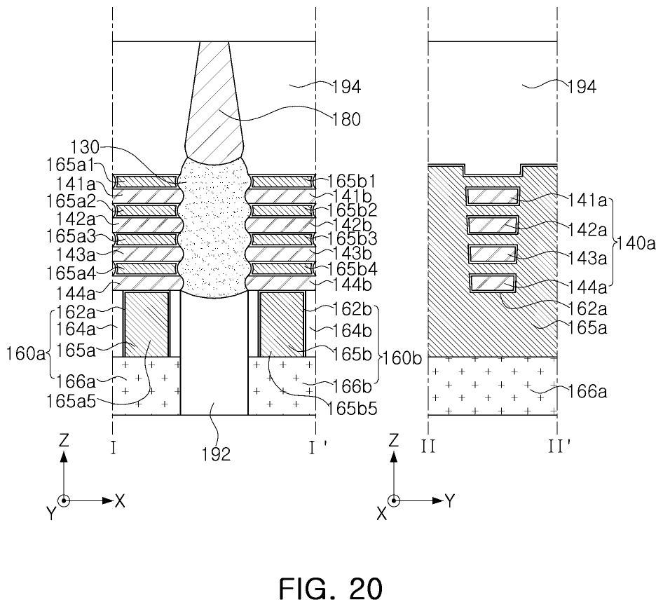

FIGS. 6A to 6B are flowcharts schematically illustrating a sequential process of a method of manufacturing a semiconductor device according to example embodiments. FIGS. 9 to 20 are drawings according to a process sequence to explain a method of manufacturing a semiconductor device according to example embodiments.

Referring to FIGS. 6A and 9, a method of manufacturing a semiconductor device according to the present example embodiment may start with forming a stack structure 140 (also referred to as the channel structure 140) on the substrate 101 (S10). The stack structure 140 may include the channel layers 141, 142, 143, and 144. Sacrificial layers 120 and the channel layers 141, 142, 143, and 144 may be alternately stacked on the substrate 101. The substrate 101 may include, for example, silicon (Si), germanium (Ge), and/or silicon germanium (SiGe). The substrate 101 may include a bulk wafer, an epitaxial layer, a silicon on insulator (SOI) layer, or a semiconductor on insulator (SeOI) layer.

The sacrificial layers 120 may be layers replaced with the gate dielectric layers 162a and 162b and the gate electrodes 165a and 165b below the channel layers 144a and 144b that are located at the highest level among the channel structures 140a and 140b, respectively through a subsequent process, as illustrated in FIG. 2A. The sacrificial layers 120 may include a material having etch selectivity with respect to the channel layers 141, 142, 143, and 144, respectively. The channel layers 141, 142, 143, and 144 may include a material, different from that of the sacrificial layers 120. The sacrificial layers 120 and the channel layers 141, 142, 143, and 144 may include, for example, a semiconductor material, such as silicon (Si), silicon germanium (SiGe), and/or germanium (Ge), may include different materials, and may or may not include impurities. For example, the sacrificial layers 120 may include silicon germanium (SiGe), and the channel layers 141, 142, 143, and 144 may include silicon (Si).

The sacrificial layers 120 and the channel layers 141, 142, 143, and 144 may be formed by performing an epitaxial growth process from the stack structure 140. Although four channel layers (e.g., the channel layers 141, 142, 143, and 144) and four sacrificial layers (e.g., the sacrificial layers 120) are illustrated in FIG. 9 the numbers of channel layers and the sacrificial layers alternately stacked with each other may be variously changed in example embodiments.

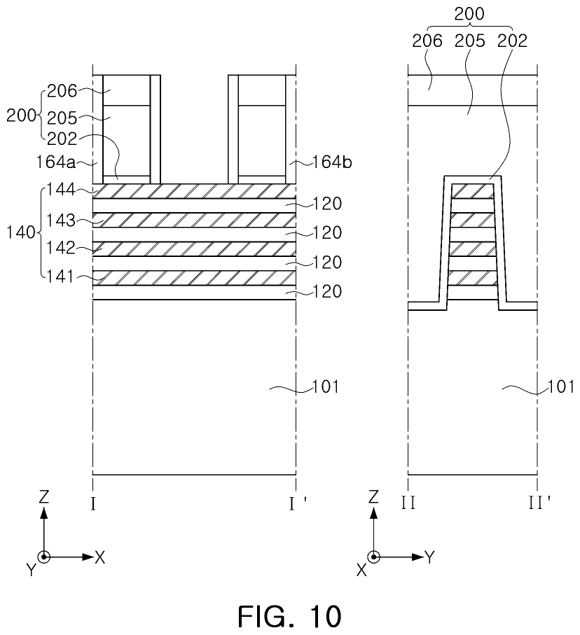

Referring to FIGS. 6A and 10, sacrificial gate structures 200 may be formed on the stack structure 140 (S20). The sacrificial gate structure 200 may be a sacrificial structure formed in a region in which the gate dielectric layers 162a and 162b and the gate electrodes 165a and 165b are disposed on the channel structures 140a and 140b, respectively through a subsequent process, as illustrated in FIG. 2A. The sacrificial gate structure 200 may have a line shape extending in one direction. For example, the sacrificial gate structures 200 may extend in the Y-direction and be spaced apart from each other in the X-direction.

The sacrificial gate structure 200 may include first and second sacrificial gate layers 202 and 205 and a mask pattern layer 206 which are sequentially stacked. The first and second sacrificial gate layers 202 and 205 may be patterned using the mask pattern layer 206. The first and second sacrificial gate layers 202 and 205 may include an insulating layer and a conductive layer, respectively, but are not limited thereto, and the first and second sacrificial gate layers 202 and 205 may be formed of a single layer. For example, the first sacrificial gate layer 202 may include silicon oxide, and the second sacrificial gate layer 205 may include polysilicon. The mask pattern layer 206 may include, for example, silicon oxide and/or silicon nitride.

The gate spacer layers 164 may be formed on both (e.g., opposite) sidewalls of the sacrificial gate structures 200. The gate spacer layers 164 may include, for example, a low-κ material, SiO, SiN, SiCN, SiOC, SiON, and/or SiOCN.

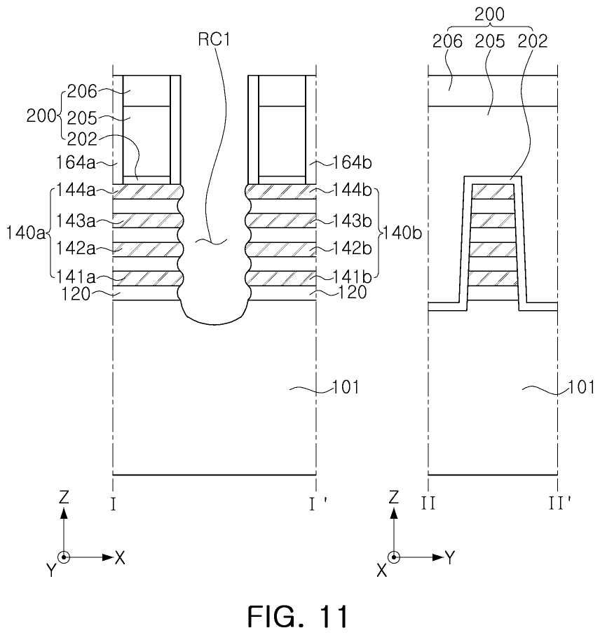

Referring to FIGS. 6A and 11, an etching process using the sacrificial gate structures 200 as an etching mask may be performed to form a first recess region RC1 extending in (e.g., penetrating or passing through) the stack structure 140 and exposing the substrate 101 (S30). Accordingly, the first and second channel layers 141a, 142a, 143a, and 144a and 141b, 142b, 143b, and 144b may be formed and comprise channel structures 140a and 140b having a limited length in the X-direction.

The sacrificial layers 120 may be selectively etched with respect to the channel structures 140a and 140b (first and second channel layers 141a, 142a, 143a, and 144a and 141b, 142b, 143b, and 144b) by, for example, a wet etching process, and may be (at least partially) removed to a predetermined depth from a side surface in the X-direction. The sacrificial layers 120 may have side surfaces that are concave inwardly due to the lateral etching as described above. However, a specific shape of the side surfaces of the sacrificial layers 120 is not limited to that shown in FIG. 11.

Referring to FIGS. 6A and 12 to 13, a spacer L may be formed on the side surfaces of the sacrificial gate structures 200 and the side surfaces of the first recess region RC1 (S40), and a portion of the substrate 101 below the first recess region RC1 may be etched through an etching process using the spacer L and the sacrificial gate structures 200 as an etching mask to form the second recess region RC2 (S50). In this process, portions in which the slopes of the side surfaces of the first and second recess regions RC1 and RC2 discontinuously change (with a kink) may be formed. The second recess region RC2 may have a shape in which the width continuously decreases toward a lower surface of the substrate 101 after partially having a section in which the width of the second recess region RC2 widens toward the lower surface of the substrate 101.

Referring to FIGS. 6A and 14 to 16, after a mold epitaxial layer 151 is formed in the second recess region RC2 (S60), the spacer L may be removed (S70), and the source/drain epitaxial layer 130 may then be formed in the first recess region RC1 (S80).

The mold epitaxial layer 151 may be formed to grow through a bottom surface of the second recess region RC2 by a selective epitaxial process. The mold epitaxial layer 151 may have a composition different from that of the source/drain epitaxial layer 130 formed in a follow-up process.

The source/drain epitaxial layer 130 may be formed to grow from an upper surface of the mold epitaxial layer 151 and the side surfaces of the channel structures 140a and 140b by, for example, a selective epitaxial process.

In the process of forming the mold epitaxial layer 151, the portion in which the slopes of the side surfaces of the first and second recess regions RC1 and RC2 are discontinuously changed may serve to control the growth of the mold epitaxial layer 151, and accordingly, reliability of the formation of the source/drain epitaxial layer 130 may be improved.

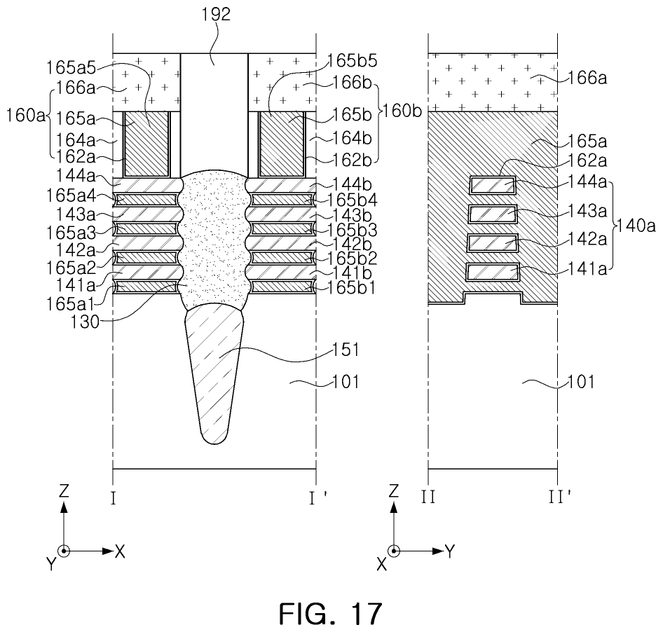

Referring to FIGS. 6B and 17, an interlayer insulating layer 192 may be formed between the sacrificial gate structures 200 (S90), gate trenches may be formed by removing at least some of the sacrificial gate structures 200 (S100), empty spaces may be formed by removing the sacrificial semiconductor layers (e.g., sacrificial layers 120) in the stack structure 140 exposed by the gate trenches (S110), and the gate structures 160a and 160b (e.g., the gate electrodes 165a and 165b) may be formed in the empty spaces and the gate trenches (S120).

The interlayer insulating layer 192 may be formed by forming an insulating film covering the sacrificial gate structures 200 and the source/drain epitaxial layer 130 and performing a planarization process.

The sacrificial gate structures 200 and the sacrificial layers 120 may be selectively removed with respect to the gate spacer layers 164a and 164b, the interlayer insulating layer 192, and the channel structures 140a and 140b. First, upper gap regions may be formed by removing the sacrificial gate structures 200, and then lower gap regions may be formed by removing the sacrificial layers 120 exposed through the upper gap regions.

For example, when the sacrificial layers 120 include silicon germanium (SiGe) and the channel structures 140a and 140b include silicon (Si), the sacrificial layers 120 may be selectively removed with respect to the channel structures 140a and 140b by performing a wet etching process. For example, when the sacrificial layers 120 include a relatively high concentration of germanium (Ge), and the source/drain epitaxial layer 130 includes a relatively low concentration of germanium (Ge), the sacrificial layers 120 may be selectively removed with respect to the source/drain epitaxial layer 130.

Although not specifically shown, contact structures and interconnection lines connected (e.g., electrically connected) to the gate structures 160a and 160b may be further formed on the gate structures 160a and 160b.

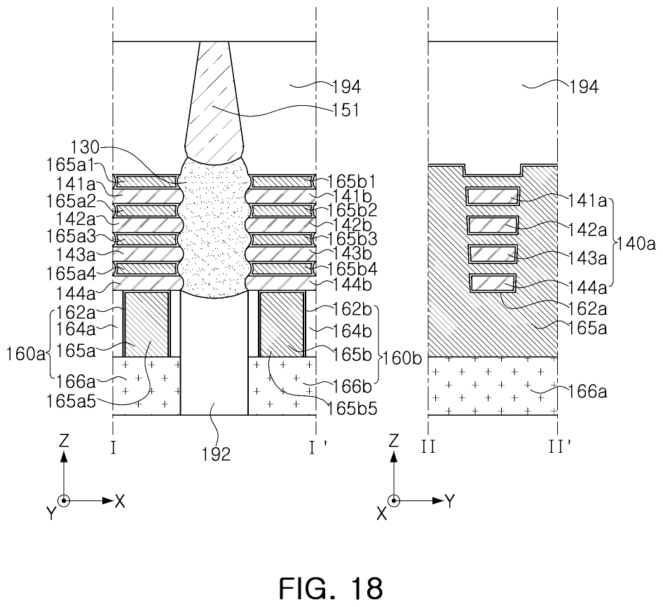

Referring to FIGS. 6B and 18, in order to perform a process on the lower surface of the substrate 101, a carrier substrate may be attached to the interlayer insulating layer 192 of the entire structure formed as described above with reference to FIGS. 9 to 17. In the following drawings, including FIG. 18, for ease of understanding, the entire structure is illustrated as being rotated or reversed in the form of a mirror image of the structure illustrated in FIG. 17.

The substrate 101 may be removed to expose the mold epitaxial layer 151 (S130), and the substrate layer 194 on (e.g., covering) at least the side surface of the mold epitaxial layer 151 may be formed (S140). The substrate layer 194 may be formed in a region from which the substrate 101 is removed.

The substrate 101 may be removed from the upper surface of the substrate 101. The substrate 101 may be removed and thinned by, for example, a lapping, grinding, or polishing process, and a remaining region may also be removed by an etching and/or oxidation process. However, a thickness from which the substrate 101 is removed may be variously changed in the example embodiments. In some example embodiments, the substrate 101 may not be completely removed and partially remain. The mold epitaxial layer 151 exposed by removing the substrate 101 may be selectively removed by an etching process in a subsequent process.

Referring to FIGS. 6B and 19 to 20, the mold epitaxial layer 151 may be removed to form a contact hole CTH (S150), and a backside contact structure 180 may be formed in the contact hole CTH (S160). Next, referring to FIG. 2 together, after forming the rear insulating layer 196 on the backside contact structure 180 and the substrate layer 194, a portion of the rear insulating layer 196 may be removed to form the backside interconnection 190 (S170).

As a result, the semiconductor device 100 of FIG. 2 may be manufactured. The semiconductor device 100 may be packaged in a state in which the backside interconnection 190 is located on the upper side of the semiconductor device 100, but is not limited thereto.

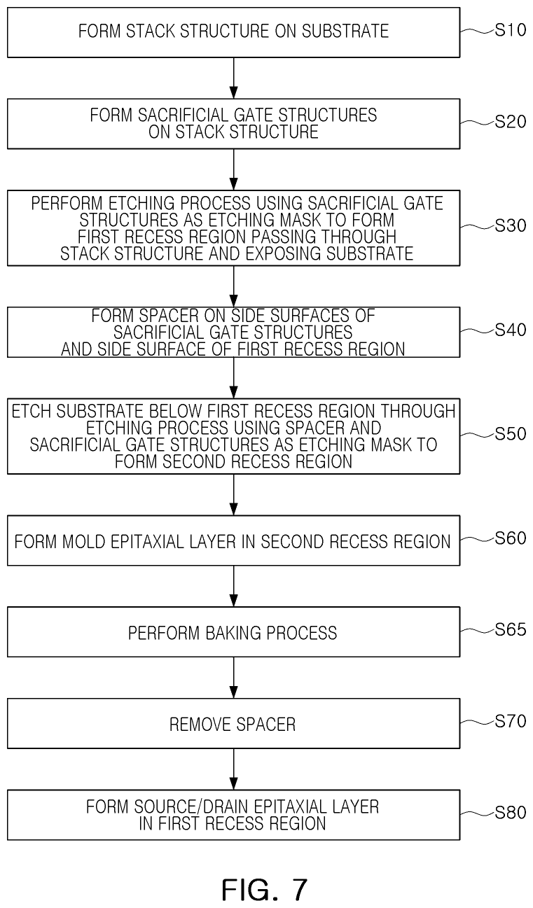

FIG. 7 is a flowchart schematically illustrating a sequential process of a method of manufacturing a semiconductor device according to example embodiments.

Referring to FIG. 7, after the mold epitaxial layer 151 is formed in the second recess region RC2 (S60), a baking process may be performed (S65), and thereafter, the spacer L may be removed. (S70).

Through the baking process, portions in which the slopes of the first and second recess regions RC1 and RC2 discontinuously change may be removed, and the side surface of the lower portion of the first recess region RC1 and the side surface of the second recess region RC2 may have a constant slope. As a result, the semiconductor device 100c of FIG. 4 may be manufactured.

Other processes may be performed in the same manner as those of FIGS. 6A to 6B and 9 to 20.

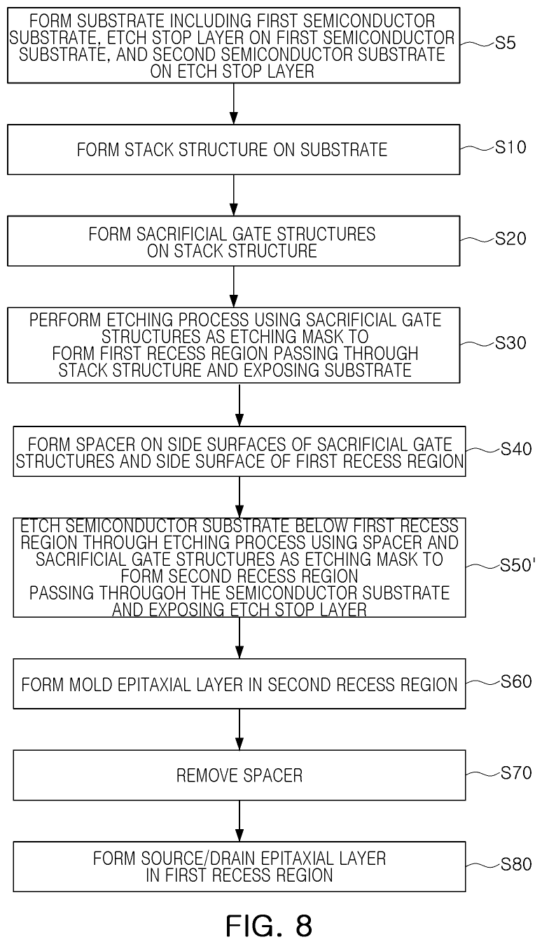

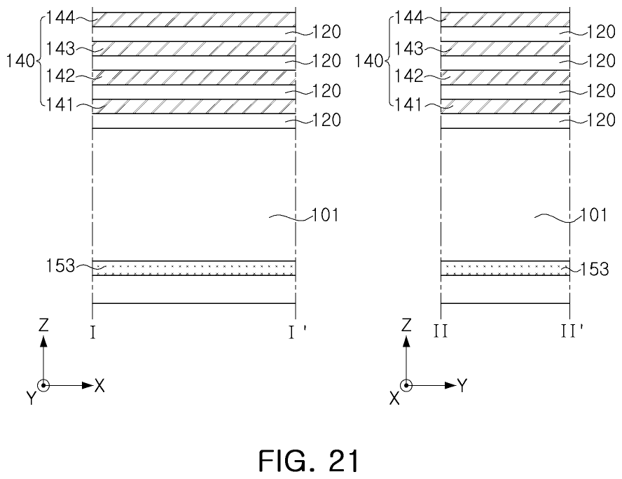

FIG. 8 is a flowchart schematically illustrating a sequential process of a method of manufacturing a semiconductor device according to example embodiments. FIGS. 21 to 23 are views illustrating a process sequence to explain a method of manufacturing a semiconductor device according to example embodiments.

In the descriptions of the following example embodiments, the same descriptions as those given above with reference to FIGS. 6A to 6B and 9 to 20 may be omitted.

Referring to FIGS. 8 and 21, before the operation (S10) of forming the stack structure 140 on the substrate 101, an operation (S5) of forming the substrate 101 including a first semiconductor substrate, the etch stop layer 153 on the first semiconductor substrate, and a second semiconductor substrate on the etch stop layer 153 may be performed. Thereafter, the operation (S10) of forming a stack structure 140 on the substrate 101 including the etch stop layer 153 may be performed.

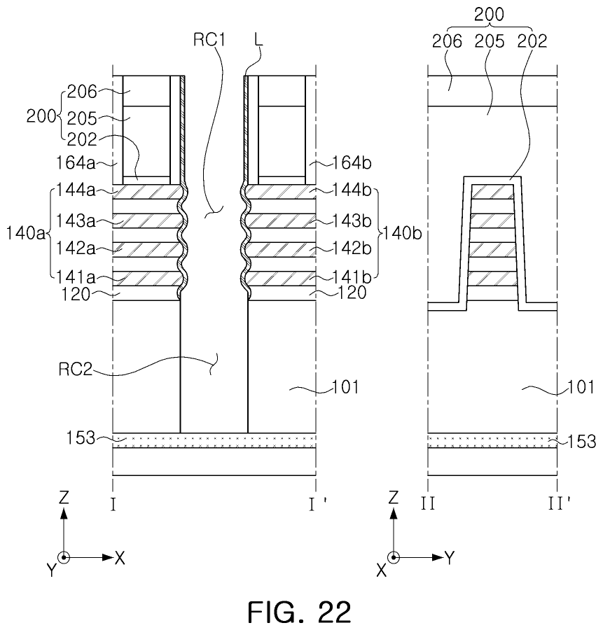

Referring to FIGS. 8 and 22, the first and second recess regions RC1 and RC2 may be formed to expose the etch stop layer 153. The etch stop layer 153 may prevent the lower end of the second recess region RC2 from being excessively deep during process of forming the second recess region RC2 and widen the lower width of the second recess region RC2. Accordingly, the maximum width of the second recess region RC2 may be greater than the minimum width of the first recess region RC1. According to an example embodiment, the width of the second recess region RC2 may be variously modified. For example, according to an example embodiment, the second recess region RC2 may have a side surface inclined to widen toward the etch stop layer 153.

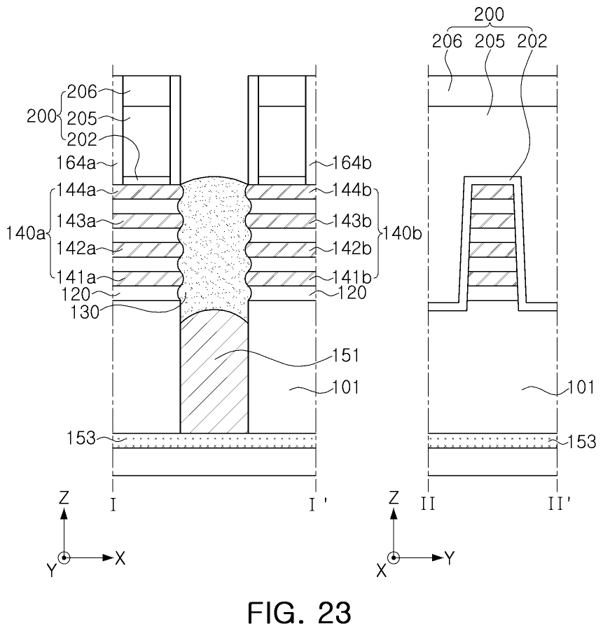

Referring to FIGS. 8 and 23, the maximum width of the mold epitaxial layer 151 may be formed to be greater than the minimum width of the source/drain epitaxial layer 130, and as subsequent processes are performed, the semiconductor device 100d of FIG. 5 may be formed.

A semiconductor device having improved reliability may be provided by disposing the backside contact structure in various shapes by variously changing the recess process, such as performing a secondary recess after a primary recess.

While example embodiments have been illustrated and described above, it will be apparent to those skilled in the art that modifications and variations could be made without departing from the scope of the present inventive concept as defined by the appended claims.

What is claimed is:

1. A semiconductor device comprising:
a substrate layer;
first channel layers that are spaced apart from each other on the substrate layer in a first direction, wherein the first direction is perpendicular to an upper surface of the substrate layer;
second channel layers that are spaced apart from each other on the substrate layer in the first direction and spaced apart from the first channel layers;
a first gate structure that extends in a second direction and extends around each of the first channel layers, wherein the second direction is parallel with the upper surface of the substrate layer;
a second gate structure that extends in the second direction and extends around each of the second channel layers;
a source/drain epitaxial layer between the first channel layers and the second channel layers;
a backside contact structure that is electrically connected to the source/drain epitaxial layer, wherein the backside contact structure is between the source/drain epitaxial layer and a lower surface of the substrate layer in the first direction; and
an interlayer insulating layer on the source/drain epitaxial layer,
wherein, along a third direction that is parallel with the upper surface of the substrate layer, a first width of the source/drain epitaxial layer at the upper surface of the substrate layer is greater than a second width at an interface between the source/drain epitaxial layer and the backside contact structure,
wherein a first portion of the backside contact structure is closer than a closest end of the source/drain epitaxial layer to the lower surface of the substrate layer,
wherein the lower surface of the substrate layer is opposite to the upper surface of the substrate layer along the first direction,
wherein the first portion of the backside contact structure has a third width, and
wherein the third width is greater than the second width.

2. The semiconductor device of claim 1, wherein a farthest end of the backside contact structure from the lower surface of the substrate layer is located farther than the closest end of the source/drain epitaxial layer from the lower surface of the substrate layer.

3. The semiconductor device of claim 1, wherein an upper surface of the backside contact structure is convex toward the source/drain epitaxial layer.

4. The semiconductor device of claim 1, wherein a lower surface of the source/drain epitaxial layer is convex toward the backside contact structure.

5. The semiconductor device of claim 1, wherein a second portion of the backside contact structure that has the second width is closer to the first portion of the backside contact structure that has the third width than to a third portion of the source/drain epitaxial layer that has the first width.

6. The semiconductor device of claim 1, wherein the backside contact structure has a fourth width in the third direction at the lower surface of the substrate layer, and
the fourth width is less than the second width.

7. The semiconductor device of claim 1, wherein, the third width of the backside contact structure is less than a maximum width of the source/drain epitaxial layer in the third direction.

8. The semiconductor device of claim 1, wherein a distance between a third portion of the source/drain epitaxial layer, which has the first width, and a second portion of the backside contact structure, which has the second width, in the first direction is greater than a thickness of at least one of the first channel layers and/or one of the second channel layers in the first direction.

9. The semiconductor device of claim 1, further comprising a backside interconnection on the lower surface of the substrate layer and electrically connected to the backside contact structure.

10. The semiconductor device of claim 9, wherein a width of an upper surface of the backside interconnection in the third direction is greater than a width of a lower surface of the backside contact structure, and
wherein the upper surface of the backside interconnection and the lower surface of the backside contact structure are in contact to each other at the lower surface of the substrate layer.

11. A semiconductor device comprising:
a substrate layer;
first channel layers that are spaced apart from each other on the substrate layer in a first direction, wherein the first direction is perpendicular to an upper surface of the substrate layer;
second channel layers that are spaced apart from each other on the substrate layer in the first direction and spaced apart from the first channel layers;
a first gate structure that extends in a second direction and extends around each of the first channel layers, wherein the second direction is parallel with the upper surface of the substrate layer;
a second gate structure that extends in the second direction and extends around each of the second channel layers;
a source/drain epitaxial layer between the first channel layers and the second channel layers;
a backside contact structure that is electrically connected to the source/drain epitaxial layer, wherein the backside contact structure is between the source/drain epitaxial layer and a lower surface of the substrate layer in the first direction; and
an interlayer insulating layer on the source/drain epitaxial layer,
wherein at least a portion of the backside contact structure has a side surface that is inclined such that a width of the backside contact structure in a third direction increase toward the source/drain epitaxial layer,
wherein the lower surface of the substrate layer is opposite to the upper surface of the substrate layer in the first direction, and
wherein the third direction is parallel with the upper surface of the substrate layer and perpendicular to the second direction.

12. The semiconductor device of claim 11, wherein a portion of the source/drain epitaxial layer closer than the upper surface of the substrate layer to the lower surface of the substrate layer in the first direction has a side surface that is inclined so that a width of the source/drain epitaxial layer in the third direction decreases toward the backside contact structure.

13. The semiconductor device of claim 11, wherein an uppermost end of the backside contact structure is farther than a lowermost end of the source/drain epitaxial layer from the lower surface of the substrate layer in the first direction.

14. The semiconductor device of claim 11, wherein an upper surface of the backside contact structure is convex toward the source/drain epitaxial layer.

15. The semiconductor device of claim 11, further comprising a backside interconnection on the lower surface of the substrate layer and electrically connected to the backside contact structure.

16. A semiconductor device comprising:
a substrate layer;
first channel layers that are spaced apart from each other on the substrate layer in a first direction, wherein the first direction is perpendicular to an upper surface of the substrate layer;
second channel layers that are spaced apart from each other on the substrate layer in the first direction and spaced apart from the first channel layers;
a first gate structure that extends in a second direction and extends around each of the first channel layers, wherein the second direction is parallel with the upper surface of the substrate layer;
a second gate structure that extends in the second direction and extends around each of the second channel layers;
a source/drain epitaxial layer between the first channel layers and the second channel layers;
a backside contact structure that is electrically connected to the source/drain epitaxial layer, wherein the backside contact structure is between the source/drain epitaxial layer and a lower surface of the substrate layer; and
an interlayer insulating layer on the source/drain epitaxial layer,
wherein the lower surface of the substrate layer is opposite to the upper surface of the substrate layer in the first direction,
an interface between the source/drain epitaxial layer and the backside contact structure is closer than the first gate structure and second gate structure that are adjacent to the source/drain epitaxial layer to the upper surface of the substrate layer,
a maximum width of the backside contact structure in a third direction is greater than a minimum width of the source/drain epitaxial layer in the third direction,
the source/drain epitaxial layer has the minimum width in the third direction at a same distance as at least one of the first channel layers from the upper surface of the substrate layer in the first direction, and
the third direction is parallel with the upper surface of the substrate layer and perpendicular to the second direction.

17. The semiconductor device of claim 16, wherein an upper surface of the backside contact structure is convex toward the source/drain epitaxial layer.

18. The semiconductor device of claim 16, wherein
the substrate layer includes an insulating layer, and
the insulating layer is on a side surface of the backside contact structure and a side surface of the source/drain epitaxial layer that is closer than the first gate structure and the second gate structure to the lower surface of the substrate layer in the first direction.

19. The semiconductor device of claim 18, wherein an upper surface of the insulating layer of the substrate layer is farther than an upper end of the backside contact structure from the lower surface of the substrate layer in the first direction.

20. The semiconductor device of claim 16, further comprising a backside interconnection that is on the lower surface of the substrate layer and electrically connected to the backside contact structure.
